(19) United States
(12) Patent Application Publication
(10) Pub. No.: US 2026/0250837 A1
(43) Pub. Date: Aug. 27, 2026

(54) PLASMA ENHANCED VAPOR DEPOSITION PROCESS AND METHOD FOR FORMING AN ELEMENTAL ANTIMONY FILM ON A SUBSTRATE

(71) Applicant: Tokyo Electron Limited, Tokyo (JP)

(72) Inventor: Robert Clark, Lueven (BE)

(21) Appl. No.: 19/065,658

(22) Filed: Feb. 27, 2025

(51) Int. Cl. C23C 16/14; C23C 8/24; C23C 16/02; C23C 16/455; C23C 16/50; C23C 28/00; H01L 21/285

(52) U.S. Cl. CPC C23C 16/14; C23C 8/24; C23C 16/0227; C23C 16/45536; C23C 16/45553; C23C 16/50; C23C 28/32; H10P 14/43

(57) ABSTRACT

Embodiments of process flows, systems and methods to form an elemental antimony (Sb) film on a semiconductor substrate are provided herein. In the disclosed embodiments, an elemental Sb film is deposited on a surface of a semiconductor substrate using a plasma enhanced chemical vapor deposition (PECVD) or plasma enhanced atomic layer deposition (PEALD) process. Unlike previous deposition methods, the disclosed embodiments do not utilize organic antimony precursors to deposit the elemental Sb film. Instead, the disclosed embodiments use a vaporized antimony halide precursor combined with a hydrogen (H₂) plasma to form an elemental Sb film on the substrate surface.

### TECHNICAL FIELD

The present disclosure relates to the processing of semiconductor substrates. In particular, it provides improved processes and methods for depositing elemental antimony films and forming antimony metal-semiconductor contacts on semiconductor substrates.

### BACKGROUND

Metal-semiconductor contacts are crucial components in the fabrication of semiconductor devices. Field effect transistors, or FETs, are one example of devices that may be formed on a semiconductor substrate using a variety of semiconductor processing techniques. The fabrication of FETs typically involves multiple steps of layer deposition, patterning and etching to define various structures on and/or within a substrate. For example, one type of FET may generally include a source region, a drain region, a channel region positioned between the source region and the drain region, and a gate structure (or simply “gate”) positioned over the channel region.

In a planar FET, such as a metal-oxide-semiconductor field effect transistor (MOSFET), the source, drain and channel regions are formed within the substrate, and the gate structure is formed above the substrate over the channel region. Unlike planar FETs, FinFET transistors are three-dimensional (3D) transistor designs that use “fins” to form a raised channel between the source and drain regions of the FinFET. In a FinFET design, the gate structure wraps around the raised channel on multiple sides of the fin to form the gate structure. The greater surface area between the gate and the channel reduces leakage currents in the transistor “off” state and enables lower gate voltages to be used to turn the FinFET “on.” Thus, FinFETs typically provide better performance and reduced power consumption compared to planar MOSFET designs.

In both planar and 3D transistor designs, metal contacts are formed in electrical contact with the source, drain and gate regions to facilitate current flow through the transistor. A metal-semiconductor contact is formed when the metal contact is electrically connected to a semiconductor material, such as a doped (or undoped) semiconductor material provided within the source and/or drain region of the transistor. A wide variety of metals have been used to form metal contacts and metal-semiconductor contacts in transistors and other semiconductor devices. For example, metals like aluminum (Al), titanium (Ti), cobalt (Co), nickel (Ni), copper (Cu), tungsten (W) and ruthenium (Ru) have traditionally been used.

The design and optimization of metal-semiconductor contacts is essential for achieving efficient, reliable, and high-performance transistor operation. The importance of metal-semiconductor contacts arises from several key factors:

Electrical Properties: Metal-semiconductor contacts facilitate the injection and extraction of charge carriers (electrons and holes) between the metal and semiconductor. The quality of this contact directly affects the electrical performance of the device, including its overall conductivity and resistivity.

Contact Resistance: The contact resistance at the metal-semiconductor interface can significantly impact the performance of transistors. Low contact resistance is essential for efficient current flow, reducing power loss, and enhancing the speed of the device. High contact resistance can lead to diminished performance, increased heat generation, and potentially thermal failure. In some cases, a metal silicide (such as, e.g., a titanium, cobalt, nickel or tungsten silicide) may be formed at the metal-semiconductor interface to reduce the contact resistance.

Schottky Barrier Formation: When a metal contacts a semiconductor, a potential barrier (Schottky barrier) can form at the interface, depending on the work functions of the metal and the semiconductor materials used. The Schottky barrier affects the behavior of the device, influencing its turn-on voltage, switching characteristics, and overall efficiency. In some cases, a barrier metal layer with an appropriate work function metal (e.g., titanium, tungsten, tantalum, etc.) may be provided between the metal contact and the semiconductor substrate to lower the Schottky Barrier Height (SBH) and decrease the contact resistance at the metal-semiconductor interface. When fabricating n-channel MOSFET (nMOSFET) devices, for example, the barrier metal layer may comprise a metal having a lower work function than the work function of the metal used to form the metal contact to reduce the SBH and contact resistivity at the metal-semiconductor interface.

Doping and Band Alignment: The choice of metal and its doping level can help tune the energy band alignment at the metal-semiconductor interface. Proper band alignment is critical for optimizing the operation of transistors, particularly in defining on/off states in FETs or ensuring proper modulation of carrier populations in other types of transistors.

Thermal Stability: The thermal stability of metal-semiconductor contacts is vital during device operation. Devices often operate at various temperatures, and stable contacts under thermal stress ensure reliable performance over the operational life of the transistor. In addition, once the metal-semiconductor contact is formed, it must be thermally stable enough to withstand the thermal budget of subsequent processes used for integrated circuit fabrication without substantially degrading the contact resistance.

Material Compatibility: The selected metal and semiconductor materials should exhibit good interfacial properties to minimize defects and ensure uniform contact across the surface area. Appropriate compatibility can prevent issues, such as metal diffusion into the semiconductor, which could alter its doping profile and degrade device performance.

Device Architecture: In many modern transistor technologies, especially in advanced technologies like FinFETs, nano-sheet/nano-wire/nano-ribbon FETs, complementary FETs (CFETs), 2D MOSFETs, transition metal dichalcogenide (TMD) MOSFETS, carbon nanotube (CNT) FETs, graphene FETs and heterojunction bipolar transistors, metal-semiconductor contacts are integral to the architecture, allowing for more efficient designs that leverage unique material properties and reduced dimensions.

Recently, researchers have investigated the use of antimony (Sb) in metal-semiconductor contacts due to its unique properties that enable low contact resistance and high carrier mobility. For example, antimony's semi metallic nature naturally forms a low Schottky barrier and creates a near-ohmic contact with many semiconductor materials. In doing so, the use of antimony in the metal-semiconductor contact minimizes the contact resistance at the metal-semiconductor interface, which is crucial for efficient charge carrier flow. When antimony is deposited onto a semiconductor surface, a weak interface forms due to van der Walls interactions, allowing for good electrical contact to the semiconductor surface with minimal disruption to the semiconductor's electronic structure. Due to its weak van der Waals interactions, antimony may be particularly well-suited for making contacts with CNT and 2D materials (like silicene and graphene, or molybdenum disulfide (MoS₂), tungsten diselenide (WSe₂) and other TMDs), where minimizing disruption to the electronic structure of the CNT or 2D material is crucial for high performance. Antimony also exhibits an adventitious band alignment with CNTs and 2D materials decreasing the Schottky barrier at the metal-semiconductor interface and exhibits good thermal stability at elevated temperatures. Due to these favorable properties, antimony is particularly attractive for creating metal-semiconductor contacts in advanced transistor devices, where minimizing contact resistance is critical for device performance. However, fabricating high-quality antimony contacts often requires specialized deposition techniques to achieve the desired interface properties.

A wide variety of deposition techniques have been used to form antimony-containing films (e.g., films containing antimony and potentially other components, such as oxides, nitrides, halides, sulfides, chalcogenides, etc.) on a substrate surface. For example, antimony trioxide (Sb₂O₃), antimony nitride (SbN), antimony sulfide (Sb₂S₃), antimony selenide (Sb₂Se₃), antimony telluride (Sb₂Te₃), germanium antimonide (GeSb) and other antimony-containing films have been formed on substrates using electrochemical deposition, chemical bath deposition, thermal sputtering, thermal evaporation, spin coating, chemical vapor deposition (CVD), aerosol assisted CVD (AACVD), metal organic CVD (MOCVD), and thermal or plasma enhanced atomic layer deposition (ALD). However, with the exception of SbN, these antimony-containing films are typically insulators or semiconductors and are generally unsuitable for forming low resistance metal-semiconductor contacts. In addition, metallic Sb may provide a better interface and band alignment with CNTs and 2D materials than SbN and other antimony-containing films. Thus, metallic Sb is preferred over other antimony-containing films for forming low resistivity metal-semiconductor contacts.

Elemental antimony (Sb) films (e.g., substantially pure Sb films) have been deposited on substrates using a combination of antimony precursors in an ALD process. For example, elemental Sb films have been deposited by ALD using dehalosilylation reactions of various organic antimony precursors (e.g., antimony precursors containing ethyl (Et) or methyl (Me) groups). In one such ALD process, antimony trichloride (SbCl₃) and Tris(triethylsilyl)antimony ((SiEt₃)₃Sb) precursors were used to form an elemental Sb film via a dechlorosilylation reaction. Dechlorosilylation reactions between SbCl₃ and Tris(trimethylsilyl)antimony ((SiMe₃)₃Sb) have also been used to form elemental Sb films in other ALD processes.

Elemental Sb films have also been deposited without the use of an antimony halide precursor (such as SbCl₃) by using a combination of organic antimony precursors. For example, a combination of antimony ethoxide (Sb(OEt)₃)) and (SiMe₃)₃Sb precursors, and a combination of Tris(dimethylamido)antimony (Sb(NMe₂)₃) and (SiMe₃)₃Sb precursors, have been used to deposit elemental Sb films in a thermal ALD process. In the thermal ALD processes, the elemental Sb films were formed via desilylation of (SiMe₃)₃Sb by Sb(OEt)₃ or Sb(NMe₂)₃.

The conventional methods described above utilize various organic antimony precursors containing carbon (C) and other elements such as silicon (Si), nitrogen (N) or oxygen (O) to form elemental Sb films in an ALD process. The use of such precursors results in Sb films containing impurities of C, Si, N, O, or combinations thereof, which are detrimental to the metal-semiconductor interface resistance and band alignment. Thus, processes including precursors or reactive gases containing C, Si, N or O are generally not preferred for metal-semiconductor contact formation in advanced semiconductor manufacturing.

Accordingly, it would be desirable to develop new processes for depositing elemental Sb films and new methods for forming antimony-semiconductor contacts.

### SUMMARY

The present disclosure provides various embodiments of process flows, systems and methods to form an elemental antimony (Sb) film on a substrate. In the disclosed embodiments, an elemental Sb film is deposited on a surface of a substrate using a plasma enhanced chemical vapor deposition (PECVD) or plasma enhanced atomic layer deposition (PEALD) process. Unlike previous deposition methods, the disclosed embodiments do not utilize organic antimony precursors to deposit the elemental Sb film. Instead, the disclosed embodiments use a vaporized antimony halide precursor combined with a hydrogen (H₂) plasma to form an elemental Sb film (e.g., a substantially pure Sb film containing, e.g., greater than 98% Sb, or more preferably, greater than 99% Sb) on the substrate surface.

In some embodiments, the elemental Sb film formed on the substrate surface may result in a metal-semiconductor contact, which is utilized to facilitate an electrical connection to an underlying semiconductor material. The elemental Sb film may be formed in contact with a wide range of semiconductor materials including: (a) semiconductor materials comprising silicon (Si), germanium (Ge) and mixtures thereof, (b) III-V and II-VI semiconductor materials, and (c) one-dimensional (1D) and two-dimensional (2D) semiconductor materials, such as transition metal dichalcogenides (TMDs), carbon nanotubes and graphene. Accordingly, the elemental Sb film disclosed herein may be used as a metal-semiconductor contact in a wide variety of transistor designs, including planar MOSFET and 3D FET designs, and other semiconductor devices.

According to one embodiment, a method is provided herein to deposit an antimony film on a semiconductor substrate. In general, the method may include: (a) exposing a surface of the semiconductor substrate to a dry vapor containing at least one antimony halide precursor, wherein the dry vapor does not contain an organic antimony precursor or any other precursor containing carbon (C), silicon (Si), nitrogen (N) or oxygen (O); and (b) exposing the surface of the semiconductor substrate to a hydrogen (H₂) plasma before, during or after said exposing the surface of the semiconductor substrate to the dry vapor to deposit an elemental antimony (Sb) film on the surface of the semiconductor substrate. In some embodiments, said exposing the surface of the semiconductor substrate to the dry vapor and said exposing the surface of the semiconductor substrate to the H₂ plasma are performed under vacuum and anhydrous conditions.

A wide variety of vaporized antimony halide precursors may be used in the method described above. For example, the at least one antimony halide precursor may be antimony trichloride (SbCl₃), antimony pentachloride (SbCl₅), antimony triiodide (SbI₃), antimony tribromide (SbBr₃), antimony trifluoride (SbF₃) or antimony pentafluoride (SbF₅). In one embodiment, the at least one antimony halide precursor may be antimony trichloride (SbCl₃), antimony pentachloride (SbCl₅) or a mixture thereof.

In some embodiments, additional step(s) may be performed before the method steps described above are performed to deposit an elemental Sb film on the substrate surface. In some embodiments, for example, an optional cleaning process may be performed, prior to exposing the surface of the semiconductor substrate to the dry vapor, to clean the surface of the semiconductor substrate and remove contaminants from the substrate surface. The method may further include maintaining the semiconductor substrate under vacuum during said cleaning, and between said cleaning and said exposing the surface of the semiconductor substrate to the dry vapor, to prevent reoxidation of the surface of the semiconductor substrate.

A wide variety of cleaning processes can be used to clean the surface of the semiconductor substrate. In one example embodiment, said cleaning may comprise exposing the semiconductor substrate to a hydrogen-containing vapor, while maintaining or heating the semiconductor substrate to a temperature between 20° C. and 500° C. The hydrogen-containing vapor used during the cleaning step may generally comprise at least one of hydrogen (H₂), hydrogen fluoride (HF) and ammonia (NH₃). In some embodiments, the semiconductor substrate may be heated by exposing the semiconductor substrate to a noble gas plasma. In another example embodiment, said cleaning may comprise performing an atomic layer etching (ALE) process to remove the contaminants from the surface of the semiconductor substrate. Examples of ALE processes that can be used to remove contaminants from the substrate surface are discussed further herein.

In some embodiments, additional step(s) may be performed after the method steps described above are performed to deposit an elemental Sb film on the substrate surface. In some embodiments, for example, an optional nitridation process may be performed, after the elemental Sb film is deposited on the surface of the semiconductor substrate, to form an antimony nitride layer on an exposed surface of the elemental Sb film. In one example embodiment, the method may include exposing the semiconductor substrate to a nitrogen-containing vapor and/or a nitrogen-containing plasma to form an antimony nitride layer on an exposed surface of the elemental Sb film. For example, the semiconductor substrate may be exposed to one or more of: an ammonia (NH₃) vapor, a hydrazine (N₂H₄) vapor, a nitrogen (N₂) vapor and a nitrogen (N₂) plasma. The method may further include maintaining the semiconductor substrate under vacuum during said exposing the semiconductor substrate to the nitrogen-containing vapor and/or the nitrogen-containing plasma.

In some embodiments, the method may further include continuing said exposing the surface of the semiconductor substrate to the dry vapor and said exposing the surface of the semiconductor substrate to the H₂ plasma until the elemental Sb film is deposited to a desired thickness to form a metal-semiconductor contact on the surface of the semiconductor substrate.

According to another embodiment, a method is provided herein to form a metal-semiconductor contact on a semiconductor substrate. The method may generally include: (a) cleaning a surface of the semiconductor substrate to remove surface contaminants from the surface of the semiconductor substrate; (b) exposing the surface of the semiconductor substrate to a dry vapor containing at least one antimony chloride precursor, wherein the dry vapor does not contain an organic antimony precursor or any other precursor containing carbon (C), silicon (Si), nitrogen (N) or oxygen (O); (c) exposing the surface of the semiconductor substrate to a hydrogen (H₂) plasma before, during or after said exposing the surface of the semiconductor substrate to the dry vapor to deposit an elemental antimony (Sb) film on the surface of the semiconductor substrate; and (d) continuing said exposing the surface of the semiconductor substrate to the dry vapor and said exposing the surface of the semiconductor substrate to the H₂ plasma until the elemental Sb film is deposited to a desired thickness to form the metal-semiconductor contact on the surface of the semiconductor substrate. In some embodiments, the at least one antimony chloride precursor may be antimony trichloride (SbCl₃), antimony pentachloride (SbCl₅) or a mixture thereof.

In some embodiments, said cleaning, said exposing the surface of the semiconductor substrate to the dry vapor, and said exposing the surface of the semiconductor substrate to the H₂ plasma may be performed under vacuum and anhydrous conditions.

In some embodiments, the method may include additional step(s) after the elemental Sb film is deposited on the surface of the semiconductor substrate. For example, the method may further include exposing the semiconductor substrate to a nitrogen-containing vapor and/or a nitrogen-containing plasma to form an antimony nitride layer on an exposed surface of the elemental Sb film after the elemental Sb film is deposited on the substrate surface. Like the previous steps, said exposing the semiconductor substrate to the nitrogen-containing vapor and/or the nitrogen-containing plasma may be performed under vacuum and anhydrous conditions.

In some embodiments of the methods disclosed herein, the elemental Sb film formed on the substrate surface may be a metal-semiconductor contact, which is utilized to facilitate an electrical connection to the underlying semiconductor substrate. In some embodiments, the methods disclosed herein may reduce a resistivity of the metal-semiconductor contact by performing one or more of the following: (a) exposing the semiconductor substrate to borane, diborane or phosphine gas prior to said exposing the surface of the semiconductor substrate to the dry vapor; and (b) annealing the semiconductor substrate to a temperature between 400° C. and 550° C. after the elemental Sb film is formed on the surface of the semiconductor substrate.

The methods disclosed herein can be used to deposit an elemental Sb film onto a wide range of semiconductor substrates and semiconductor materials. In some embodiments, for example, the elemental Sb film may be deposited onto a semiconductor substrate comprising silicon (Si), germanium (Ge) or a mixture thereof. In other embodiments, the elemental Sb film may be deposited onto a semiconductor substrate comprising a III-V semiconductor material or a II-VI semiconductor material. In yet other embodiments, the elemental Sb film may be deposited onto a semiconductor substrate comprising transition metal dichalcogenides, carbon nanotubes or graphene.

A wide variety of deposition processes may be used to deposit the elemental Sb film on the substrate surface in the methods described herein. In one embodiment, said exposing the surface of the semiconductor substrate to the dry vapor and said exposing the surface of the semiconductor substrate to the H₂ plasma may be performed with at least partial temporal overlap in a plasma enhanced chemical vapor deposition (PECVD) process. When a PECVD process is used, said exposing the surface of the semiconductor substrate to the dry vapor and said exposing the surface of the semiconductor substrate to the H₂ plasma may continue for an amount of time needed to deposit a desired thickness of the elemental Sb film on the surface of the semiconductor substrate.

In another embodiment, said exposing the surface of the semiconductor substrate to the dry vapor and said exposing the surface of the semiconductor substrate to the H₂ plasma may be performed sequentially with no temporal overlap in a plasma enhanced atomic layer deposition (PEALD) process. When a PEALD process is used, said exposing the surface of the semiconductor substrate to the dry vapor and said exposing the surface of the semiconductor substrate to the H₂ plasma may be repeated multiple times until a desired thickness of the elemental Sb film is deposited on the surface of the semiconductor substrate. In some embodiments, the method may further comprise exposing the surface of the semiconductor substrate to an inert gas plasma during said exposing the surface of the semiconductor substrate to the dry vapor when a PEALD process is used.

As noted above and described further herein, the present disclosure provides various embodiments of methods for depositing antimony films and forming metal-semiconductor contacts on semiconductor substrates. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method that utilizes the techniques described herein to deposit an elemental antimony (Sb) film on a semiconductor substrate.

FIG. 2 is a block diagram illustrating one embodiment of a process flow that utilizes the techniques described herein to deposit an elemental Sb film on a semiconductor substrate.

FIG. 3 is a flowchart diagram illustrating one embodiment of a method that utilizes the techniques described herein to form a metal-semiconductor contact on a semiconductor substrate.

FIG. 4 is a block diagram illustrating one embodiment of a system that utilizes the techniques described herein to deposit an elemental Sb film on a semiconductor substrate.

### DETAILED DESCRIPTION

The present disclosure provides various embodiments of process flows, systems and methods to form an elemental antimony (Sb) film on a substrate. In the disclosed embodiments, an elemental Sb film is deposited on a surface of a substrate using a plasma enhanced chemical vapor deposition (PECVD) or plasma enhanced atomic layer deposition (PEALD) process. Unlike previous deposition methods, the disclosed embodiments do not utilize organic antimony precursors to deposit the elemental Sb film. Instead, the disclosed embodiments use a vaporized antimony halide precursor combined with a hydrogen (H₂) plasma to form an elemental Sb film on the substrate surface.

In the disclosed embodiments, an elemental Sb film is deposited on the surface of a semiconductor substrate. The semiconductor substrate may be a base semiconductor substrate or may be a semiconductor substrate having one or more semiconductor processing layers (all of which together may comprise the substrate) formed thereon. In one embodiment, the semiconductor substrate may be a substrate that has been subject to multiple semiconductor processing steps, which yield a wide variety of structures and layers, all of which are known in the substrate processing art, and which may be considered to be part of the substrate. For example, in one embodiment, the semiconductor substrate may be a semiconductor wafer having one or more semiconductor processing layers formed thereon. The techniques disclosed herein may be utilized at any stage of the substrate process flow, for example, any of the numerous processing steps that may be used to form a completed substrate or a completed semiconductor device.

As used herein, an “elemental Sb film” is a substantially pure Sb film containing primarily elemental antimony (e.g., greater than 98% Sb, or more preferably, greater than 99% Sb) with very little to no other components (such as, e.g., carbides, oxides, nitrides, halides, sulfides, chalcogenides, etc.) throughout the film thickness. In some embodiments, the elemental Sb film may be formed directly on an underlying semiconductor substrate. In other embodiments, a thin interface layer may be formed between the elemental Sb film and the underlying semiconductor substrate, depending on the material used to form the semiconductor substrate and the process conditions used to form the elemental Sb film. For example, a silicide interface layer may be formed between the elemental Sb film and an underlying, silicon-containing semiconductor substrate, in some embodiments. In another example, a thin oxide or nitride interface layer may be formed between the elemental Sb film and an underlying carbon nanotube (CNT) or 2D semiconductor material containing substrate, in some embodiments. The thin oxide or nitride interface layer may comprise Sb, aluminum (Al), silicon (Si) or other elements and may be used to enhance deposition or adhesion of the Sb film on the CNT or 2D semiconductor material.

In some embodiments, the elemental Sb film formed on the surface of the semiconductor substrate may be a metal-semiconductor contact used to facilitate an electrical connection to the underlying semiconductor material. The elemental Sb film may be formed in contact with a wide range of semiconductor substrate materials including: (a) semiconductor materials comprising silicon (Si), germanium (Ge) and mixtures thereof, (b) III-V and II-VI semiconductor materials, and (c) one-dimensional (1D) and two-dimensional (2D) semiconductor materials, such as transition metal dichalcogenides (TMDs), carbon nanotubes (CNTs) and graphene. Accordingly, the elemental Sb film disclosed herein may be used as a metal-semiconductor contact in a wide variety of semiconductor devices, including planar MOSFET and 3D FET transistor designs.

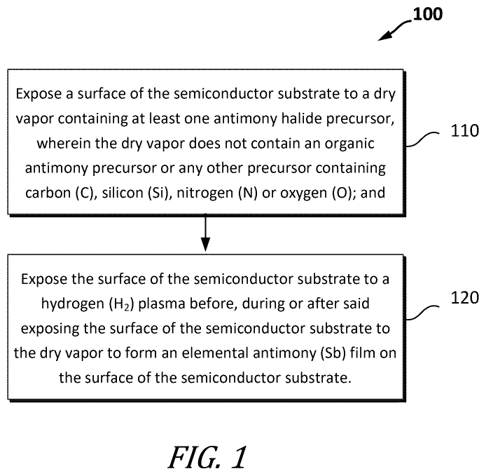

Turning now to the drawings, FIG. 1 illustrates one embodiment of a method 100 that utilizes the techniques described herein to deposit an elemental antimony (Sb) film on a semiconductor substrate. It will be recognized that the method 100 shown in FIG. 1 is merely exemplary and additional methods may utilize the techniques disclosed herein. Further, additional processing steps may be added to the method 100 as the steps described are not intended to be exclusive. Moreover, the order of the steps is not limited to the order shown in the figures as different orders may occur and/or various steps may be performed in combination or at the same time.

As shown in FIG. 1, the method 100 may generally include exposing a surface of a semiconductor substrate to a dry vapor containing at least one antimony halide precursor (in step 110) and exposing the surface of the semiconductor substrate to a hydrogen (H₂) plasma (in step 120). The dry vapor used in step 110 does not contain an organic antimony precursor or any other precursor containing carbon (C), silicon (Si), nitrogen (N) or oxygen (O). In the method 100, the surface of the semiconductor substrate is exposed to the H₂ plasma (in step 120) sometime before, during or after the surface of the semiconductor substrate is exposed to the dry vapor (in step 110) to deposit an elemental antimony (Sb) film on the surface of the semiconductor substrate.

A wide variety of vaporized antimony halide precursors may be used in the method 100. In some embodiments, the at least one antimony halide precursor may be an antimony chloride precursor, such as antimony trichloride (SbCl₃), antimony pentachloride (SbCl₅) or a mixture thereof. When an antimony chloride precursor is used in step 110, the antimony chloride precursor may be vaporized and supplied to the substrate surface as a substantially dry or anhydrous vapor to avoid reactions with water (or moisture within the reaction chamber) that may result in oxygen impurities in the elemental Sb film. However, other antimony halides may also be vaporized and used in step 110. Any antimony halide with sufficient volatility may be used in step 110. For example, antimony triiodide (SbI₃), antimony tribromide (SbBr₃), antimony trifluoride (SbF₃), or antimony pentafluoride (SbF₅) may be used. Although SbF₃ and SbF₅ can be used in the method 100, the use of fluorine-containing precursors will form hydrogen fluoride (HF) as a reaction by-product, which can etch silicon containing materials. Thus, fluorine-containing precursors may not be preferred when silicon-containing substrates or other silicon-containing films are exposed on the surface of the semiconductor substrate.

In the method 100 shown in FIG. 1, a plasma-enhanced vapor deposition process is used to deposit an elemental Sb film on a surface of a semiconductor substrate. The plasma-enhanced vapor deposition process may be, for example, a plasma enhanced chemical vapor deposition (PECVD) process or a plasma enhanced atomic layer deposition (PEALD) process. When a PECVD process is used in the method 100, steps 110 and 120 are performed simultaneously, or with at least partial temporal overlap, so that the vaporized antimony halide precursor and the H₂ plasma are provided to the substrate surface at substantially the same time. When a PEALD process is used in the method 100, steps 110 and 120 are performed sequentially, with no temporal overlap, so that the substrate surface is exposed to the vaporized antimony halide precursor and the H₂ plasma at different times.

The elemental Sb film deposited on the substrate surface using the method 100 shown in FIG. 1 is a substantially pure Sb film containing primarily elemental antimony (e.g., greater than 98% Sb, or more preferably, greater than 99% Sb) with very little to no other components (such as, e.g., carbides, oxides, nitrides, halides, sulfides, chalcogenides, etc.) throughout the film thickness. Unlike previous deposition methods used to form elemental Sb films, the plasma-enhanced vapor deposition process disclosed herein does not use organic antimony precursors (e.g., antimony precursors containing ethyl (Et) or methyl (Me) groups) or any other precursor containing carbon (C), silicon (Si), nitrogen (N) or oxygen (O) to deposit the elemental Sb film. Instead, the disclosed process uses a vaporized antimony halide precursor in combination with a hydrogen (H₂) plasma to form an elemental Sb film on the substrate surface. By avoiding the use of organic antimony precursors, the plasma-enhanced vapor deposition process disclosed herein results in Sb films substantially free from C, N, Si or O impurities.

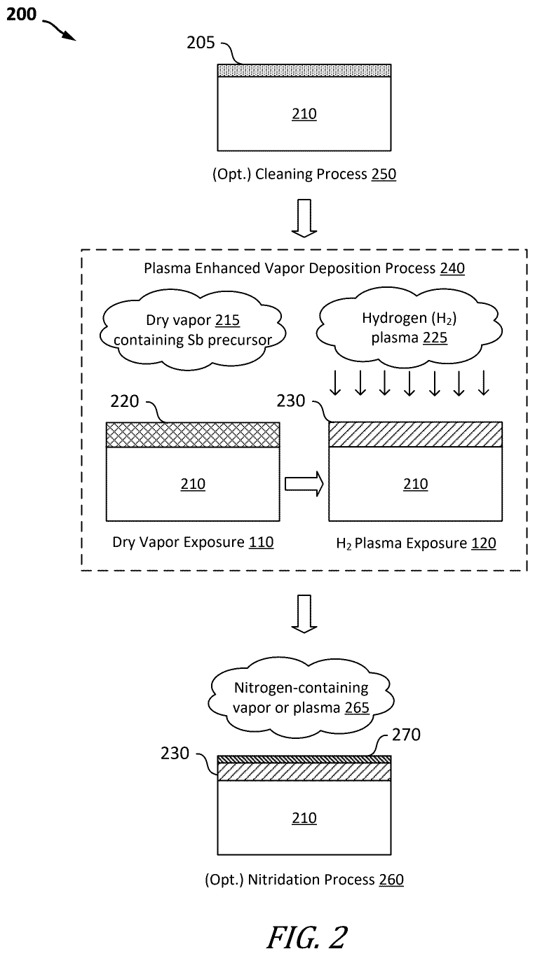

FIG. 2 illustrates one embodiment of a process flow 200 that utilizes a plasma enhanced vapor deposition process 240 to deposit an elemental antimony (Sb) film 230 on a surface of a semiconductor substrate 210 in accordance with the techniques disclosed herein. Similar to the method 100 shown in FIG. 1, the plasma enhanced vapor deposition process 240 deposits the elemental Sb film 230 on the substrate surface by: (a) exposing the substrate surface to a dry vapor 215 containing at least one antimony halide precursor (in step 110), and (b) exposing the substrate surface to a H₂ plasma 225 (in step 120) after the substrate surface is exposed to the dry vapor (in step 110). As noted above, the dry vapor 215 containing the at least one antimony halide precursor does not contain an organic antimony precursor or any other precursor containing C, Si, N or O. Examples of antimony halide precursors that may be included within the dry vapor 215 include, but are not limited to, antimony trichloride (SbCl₃), antimony pentachloride (SbCl₅) antimony triiodide (SbI₃), antimony tribromide (SbBr₃), antimony trifluoride (SbF₃), or antimony pentafluoride (SbF₅), as described above. Other antimony halide precursors not specifically mentioned herein may also be utilized within the dry vapor 215, as long as the antimony halide precursor does not contain C, Si, N or O.

In the example embodiment shown in FIG. 2, a plasma enhanced atomic layer deposition (PEALD) process is used to deposit the elemental Sb film 230 on the substrate surface. Like traditional ALD, PEALD is used to deposit ultra-thin films with atomic layer precision by utilizing a sequence of steps and self-limiting reactions to deposit material one atomic layer at a time in a cyclical deposition process. Each cycle of the PEALD process typically involves a sequence of exposures to a precursor gas followed by a purge step to remove excess reactants. Unlike traditional ALD, however, PEALD incorporates a plasma process to enhance the deposition rate and improve film properties.

When a PEALD process is used to deposit the elemental Sb film 230, the dry vapor 215 containing the gaseous antimony halide precursor and the H₂ plasma 225 are provided to the reaction chamber in non-overlapping, sequential steps. Exposing the surface of the semiconductor substrate 210 to a dry vapor 215 containing an antimony halide precursor (in step 110) may form an antimony-containing film 220 on the substrate surface, as shown in FIG. 2. The antimony-containing film 220 formed on the substrate surface in step 110 may primarily contain antimony (Sb), but may also contain other components, such as hydrides, oxides and/or halides.

When the surface of the semiconductor substrate 210 is subsequently exposed to the H₂ plasma 225 (in step 120), the H₂ plasma 225 may reduce and dehalogenate the antimony-containing film 220 to form an elemental Sb film 230 on the surface of the semiconductor substrate 210. For example, when an antimony chloride precursor (such as SbCl₃ or SbCl₅) is used in the dry vapor 215, the H₂ plasma 225 may remove oxygen impurities and chlorine ligands from the growing antimony-containing film 220 to form an elemental Sb film 230 having a zero oxidation state on the substrate surface. The elemental Sb film 230 is a substantially pure Sb film containing primarily elemental antimony (e.g., greater than 98% Sb, or more preferably, greater than 99% Sb) with very little to no other components (e.g., oxides, chlorides, etc.) throughout the film thickness. In some embodiments, the dry vapor 215 and H₂ plasma 225 exposure steps may be repeated multiple times, in a cyclical process, until a desired thickness of the elemental Sb film 230 is deposited on the substrate surface.

In some embodiments, the PEALD process described above may include one or more additional process steps. For example, purge steps may be performed between the dry vapor 215 and H₂ plasma 225 exposure steps, in some embodiments. Purge steps may be performed by supplying an inert gas (e.g., a noble gas, such as argon (Ar), nitrogen (N₂), helium (He), etc.) to the reaction chamber to remove excess reactants and/or reaction by-products from the reaction chamber. In some embodiments, an additional plasma may be created from an inert gas and supplied to the substrate surface during the dry vapor 215 exposure (step 110), during the H₂ plasma 225 exposure (step 120) and/or during the purge steps. If included, the additional plasma may generate reactive species, which assist in the deposition process.

In other embodiments (not shown in FIG. 2), a PECVD process can be used to deposit the elemental Sb film 230 on the substrate surface. When a PECVD process is used to deposit the elemental Sb film 230, the dry vapor 215 containing the gaseous antimony halide precursor(s) and the H₂ plasma 225 are supplied to the reaction chamber simultaneously, or with at least partial temporal overlap. Providing the dry vapor 215 and the H₂ plasma 225 to the reaction chamber at substantially the same time enables reactive species within the H₂ plasma 225 to react with the antimony halide precursor in the dry vapor 215 to form an antimony-containing film 220 comprising substantially pure Sb (e.g., an elemental Sb film 230 comprising greater than 98% Sb, or greater than 99% Sb) on the substrate surface. Thus, an elemental Sb film 230 may be formed on the substrate surface in a single deposition step, rather than a series of sequential steps, when a PECVD process is used. In some embodiments, the PECVD process may continue for an amount of time needed to deposit a desired thickness of the elemental Sb film 230.

Regardless of the deposition method used, the semiconductor substrate is preferably exposed to the dry vapor (in step 110) and the H₂ plasma (in step 120) under vacuum and anhydrous conditions. In some embodiments, the reaction chamber may be evacuated to a relatively low vacuum pressure (e.g., 20 Torr or less), while the method 100 shown in FIG. 1 and the process flow 200 shown in FIG. 2 are carried out, to control the gas flow of antimony halide precursor gas(es) introduced into the reaction chamber and prevent unwanted reactions between the antimony halide precursor gas(es) and atmospheric components (like oxygen, nitrogen, hydrogen and water). By performing the antimony deposition process steps (steps 110 and 120) under vacuum and anhydrous conditions, contamination in both the deposited Sb film and the reaction chamber is minimized to improve film quality and avoid damage to chamber components. The antimony deposition process steps (steps 110 and 120) may also be performed at elevated substrate temperatures. For example, the substrate temperature may range between about 250-700° C., between about 350-600° C. or between about 450-550° C., in some embodiments.

In some embodiments, the method 100 and process flow 200 may perform one or more additional steps before and/or after the plasma enhanced vapor deposition process 240. In some embodiments, for example, an optional cleaning process 250 may be performed before the surface of the semiconductor substrate 210 is exposed to the dry vapor 215 (in step 110) to remove surface contaminants 205 (e.g., a native oxide, oxygen species or other contaminants) from the substrate surface, as shown in FIG. 2. The method 100 and process flow 200 may maintain the semiconductor substrate 210 under vacuum and anhydrous conditions during the cleaning process 250, and during the transition between the cleaning process 250 and the plasma enhanced vapor deposition process 240, to prevent recontamination (e.g., reoxidation) of the substrate surface.

A wide variety of cleaning techniques may be used to remove surface contaminants 205 from the substrate surface. In some embodiments, a vapor cleaning process 250 may be used to remove surface contaminants 205 and clean the substrate surface. In one example vapor cleaning process 250, the semiconductor substrate 210 may be exposed to a hydrogen-containing vapor (e.g., a vapor comprising hydrogen (H₂), hydrogen fluoride (HF), ammonia (NH₃), or a mixture thereof), while the semiconductor substrate 210 is maintained at a temperature between 20° C. and 500° C., to remove oxides and other contaminants from the substrate surface.

A wide variety of methods may be utilized to heat the semiconductor substrate 210 during a vapor-phase cleaning process 250. In some embodiments, the semiconductor substrate 210 may be heated under vacuum pressure in the presence of the hydrogen-containing vapor, which may optionally include one or more inert gases. In one example, the substrate may be heated using a substrate holder that acts as a hot-plate. In another example, substrate heating may be performed by exposing the semiconductor substrate 210 to a noble gas plasma. However, substrate heating may also be performed in the absence of plasma excitation. In yet another example, substrate heating may be performed by optical means such laser or lamp heating. Other methods for heating the semiconductor substrate 210 during the cleaning process 250 can include, but are not limited to, using a hot filament above the substrate or using activation by e-beam, ultraviolet (UV), extreme ultraviolet (EUV), High numerical aperture (NA) EUV, or Next Gen high NA/Hyper NA EUV.

In other embodiments, an atomic layer etching (ALE) process may be used to remove the surface contaminants 205 from the semiconductor substrate 210 during the optional cleaning process 250. As known in the art, ALE is a process that removes thin layers of material (e.g., one or more monolayers at a time) sequentially through one or more self-limiting reactions. In some embodiments, an ALE process may include multiple cycles of sequential layer modification and etch steps, where the modification and etch steps combine to remove the contaminated surface layer. In such processes, a series of self-limiting reactions may occur, and the cycle may be repeatedly performed, until a desired amount of material is removed.

In one example, the cleaning process 250 may be a dry ALE process including multiple ALE cycles, where each cycle of the ALE process includes a series of surface modification and/or etch steps that expose the semiconductor substrate 210 to a reactive gas such as HF, chlorine (Cl₂), hydrogen chloride (HCl), tungsten hexafluoride (WF₆), boron trichloride (BCl₃) or trimethylaluminum (Al₂(CH₃)₆), which reacts with the surface contaminants 205 on the substrate surface to form and remove a modified surface contaminant layer from the substrate surface. In another example, the cleaning process 250 may be a dry ALE process including multiple ALE cycles, where each cycle of the ALE process includes: (a) a surface modification step that exposes the semiconductor substrate 210 to a reactive gas such as HF, Cl₂, HCl, WF₆, BCl₃ or trimethylaluminum, and (b) a plasma etch step that exposes the semiconductor substrate 210 to a plasma formed from reactive and/or inert gasses (e.g. Ar, H, CF₄, WF₆, etc.) and removes at least a portion of the modified impurity layer from the surface of the substrate. In some cases, purge or evacuation steps may be performed between the surface modification step and the etch step, as is known in the art, and the ALE process may be repeated for one or more ALE cycles until the surface contaminants 205 are removed from the substrate surface.

In some embodiments, an optional nitridation process 260 may be performed after the elemental Sb film 230 is formed on the surface of the semiconductor substrate 210, as shown in FIG. 2. During the nitridation process 260, the semiconductor substrate 210 is exposed to a nitrogen-containing vapor and/or a nitrogen-containing plasma 265 to form an antimony nitride (SbN) layer 270 on an exposed surface of the elemental Sb film 230. For example, the semiconductor substrate 210 may be exposed to an ammonia (NH₃) vapor, a hydrazine (N₂H₄) vapor, a nitrogen (N₂) vapor, a nitrogen (N₂) plasma, or a mixture thereof during the optional nitridation process 260. The SbN layer 270 formed on the surface of the elemental Sb film 230 is a thin surface layer that protects the surface from re-oxidation.

In some embodiments, the elemental Sb film 230 formed on the substrate surface may be a metal-semiconductor contact, which is utilized to facilitate an electrical connection to an underlying semiconductor material. The elemental Sb film 230 may be formed in contact with a wide range of semiconductor substrate materials including: (a) semiconductor materials comprising silicon (Si), germanium (Ge) and mixtures thereof, (b) III-V and II-VI semiconductor materials, and (c) one-dimensional (1D) and two-dimensional (2D) semiconductor materials, such as transition metal dichalcogenides (TMDs), carbon nanotubes (CNTs) and graphene. Accordingly, the elemental Sb film 230 disclosed herein may be used as a metal-semiconductor contact in a wide variety of semiconductor devices, including planar MOSFET and 3D FET transistor designs.

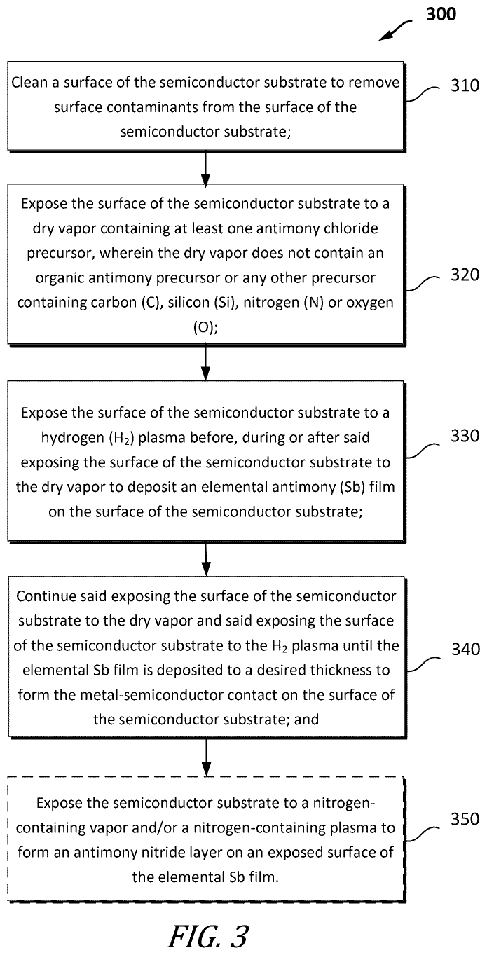

FIG. 3 illustrates one embodiment of a method 300 that utilizes the techniques disclosed herein to form a metal-semiconductor contact on a semiconductor substrate. It will be recognized that the method 300 shown in FIG. 3 is merely exemplary and additional methods may utilize the techniques disclosed herein. Further, additional processing steps may be added to the method 300 as the steps described are not intended to be exclusive. Moreover, the order of the steps is not limited to the order shown in the figures as different orders may occur and/or various steps may be performed in combination or at the same time.

As shown in FIG. 3, the method 300 may generally begin by cleaning a surface of the semiconductor substrate 210 to remove surface contaminants 205 (e.g., a native oxide, oxygen species or other contaminants) from the surface of the semiconductor substrate 210 (in step 310). A variety of cleaning processes 250 can be used in step 310 to clean the substrate surface. For example, a vapor cleaning process or an ALE process may be used to remove the surface contaminants 205 from the semiconductor substrate 210, as noted above in reference to FIG. 2.

The method 300 may further include exposing the surface of the semiconductor substrate 210 to a dry vapor 215 containing at least one antimony chloride precursor (in step 320) and exposing the surface of the semiconductor substrate 210 to a hydrogen (H₂) plasma 225 (in step 330) before, during or after said exposing the surface of the semiconductor substrate to the dry vapor to deposit an elemental antimony (Sb) film on the surface of the semiconductor substrate. In the method 300 shown in FIG. 3, the at least one antimony chloride precursor included within the dry vapor 215 is antimony trichloride (SbCl₃), antimony pentachloride (SbCl₅) or a mixture thereof. However, the dry vapor 215 does not contain an organic antimony precursor or any other precursor containing carbon (C), silicon (Si), nitrogen (N) or oxygen (O). The method 300 may continue (in step 340) to expose the surface of the semiconductor substrate 210 to the dry vapor 215 (in step 320) and the H₂ plasma 225 (in step 330) until the elemental Sb film 230 is deposited to a desired thickness to form a metal-semiconductor contact on the surface of the semiconductor substrate 210.

A variety of plasma enhanced vapor deposition process 240 can be used in steps 320, 330 and 340 to deposit the elemental Sb film 230 on the surface of the semiconductor substrate 210 and form the metal-semiconductor contact on the substrate surface. For example, a plasma enhanced chemical vapor deposition (PECVD) process or a plasma enhanced atomic layer deposition (PEALD) process may be used.

When a PECVD process is used in the method 300, steps 320 and 330 are performed simultaneously, or with at least partial temporal overlap, so that the dry vapor 215 containing the antimony chloride precursor(s) and the H₂ plasma 225 are provided to the reaction chamber at substantially the same time. Providing the dry vapor 215 and the H₂ plasma 225 to the reaction chamber at substantially the same time enables the reactive species within the H₂ plasma 225 to react with the antimony chloride precursor(s) in the dry vapor 215 to form an elemental Sb film 230 comprising substantially pure Sb (e.g., an elemental Sb film 230 comprising greater than 98% Sb, or greater than 99% Sb) on the substrate surface in a single deposition step. In some embodiments, the PECVD process may continue in step 340 for an amount of time needed to deposit a desired thickness of the elemental Sb film 230 on the substrate surface to form the metal-semiconductor contact.

When a PEALD process is used in the method 300, steps 320 and 330 are performed sequentially, with no temporal overlap, so that the surface of the semiconductor substrate 210 is exposed to the dry vapor 215 containing the antimony chloride precursor(s) and the H₂ plasma at different times. In the PEALD embodiment, the dry vapor 215 and the H₂ plasma 225 are provided to the substrate surface in non-overlapping, sequential steps. Exposing the surface of the semiconductor substrate 210 to the dry vapor 215 containing at least one antimony chloride precursor (in step 320) may form an antimony-containing film 220 on the substrate surface. The antimony-containing film 220 formed on the substrate surface in step 320 may primarily contain antimony (Sb), but may also contain other components, such as oxides and/or chlorides. When the surface of the semiconductor substrate 210 is subsequently exposed to the H₂ plasma 225 (in step 330), the H₂ plasma 225 reduces and dechlorinates the antimony-containing film 220 (e.g., removes oxygen impurities and chlorine ligands from the antimony-containing film 220) to form an elemental antimony (Sb) film 230 on the surface of the semiconductor substrate 210. In some embodiments, the PEALD process may continue in step 340 by repeating the dry vapor 215 and H₂ plasma 225 exposure steps multiple times, in a cyclical process, until a desired thickness of the elemental Sb film 230 is deposited on the substrate surface.

In some embodiments of the method 300, an optional nitridation process 260 may be performed after the elemental Sb film 230 is deposited on the substrate surface. For example, the method 300 may expose the semiconductor substrate 210 to a nitrogen-containing vapor and/or a nitrogen-containing plasma 265 to form an antimony nitride (SbN) layer 270 on an exposed surface of the elemental Sb film 230 (in step 350). In some cases, the semiconductor substrate 210 may be exposed to an ammonia (NH₃) vapor, a hydrazine (N₂H₄) vapor, a nitrogen (N₂) vapor, a nitrogen (N₂) plasma, or a mixture thereof (in step 350) to form a thin SbN layer 270 on the surface of the elemental Sb film 230, as noted above in reference to FIG. 2.

In some embodiments of the method 300, the cleaning process 250 (step 310), the plasma enhanced vapor deposition process 240 (steps 320, 330 and 340) and the optional nitridation process 260 (step 350) may be performed under vacuum and anhydrous conditions.

The methods disclosed herein can be used to deposit an elemental Sb film onto a wide range of semiconductor substrates and substrate materials. In some embodiments, the methods 100 and 300 may deposit the elemental Sb film 230 onto a semiconductor substrate 210 comprising silicon (Si), germanium (Ge) or a mixture thereof. For example, the semiconductor substrate 210 may be composed of amorphous silicon (a-Si), polycrystalline silicon (poly-Si), silicon carbide (SiC), carbon-doped silicon, silicon germanium (SiGe), germanium-doped silicon, etc. In some embodiments, a semiconductor substrate 210 comprising silicon (Si) and/or germanium (Ge) may be doped with various elements, depending on the semiconductor device being formed. For example, a silicon-and/or germanium-containing substrate may be doped with arsenic (As) or phosphorus (P) when forming an n-channel MOSFET (nMOSFET) device, or doped with boron (B) or gallium (Ga) when forming a p-channel MOSFET (pMOSFET) device.

In other embodiments, the methods 100 and 300 may deposit the elemental Sb film 230 onto a semiconductor substrate 210 comprising a III-V or II-VI semiconductor material. III-V semiconductors are alloys made from elements in group 3 (e.g., aluminum (Al), gallium (Ga), indium (In), and boron (B)) and group 5 (e.g., arsenic (As), nitrogen (N), phosphorus (P), and antimony (Sb)) of the periodic table. Likewise, II-VI semiconductors are alloys made from elements in group 2 or 12 (e.g., magnesium (Mg), cadmium (Cd), zinc (Zn), and mercury (Hg)) and non-metallic elements of group 16 (e.g., oxygen (O), sulfur(S), selenium (Se), tellurium (Te) and other chalcogens) of the periodic table. III-V and II-VI semiconductor materials typically exhibit much higher electron mobility than silicon, allowing for faster switching speeds and improved signal transmission at high frequencies. For this reason, transistors and other semiconductor devices utilizing III-V or II-VI semiconductor materials are often used in high-speed, high-frequency applications, making them ideal for devices like microwave amplifiers, optoelectronic components and high-performance integrated circuits. Common examples of III-V materials used in transistors include Gallium Arsenide (GaAs), Indium Phosphide (InP), and Gallium Nitride (GaN), while Cadmium Selenide (CdSe) is a common II-VI semiconductor used in similar applications.

In yet other embodiments, the methods 100 and 300 may deposit the elemental Sb film 230 onto a semiconductor substrate 210 comprising a 1D or 2D semiconductor material used in advanced transistor technologies, such as transition metal dichalcogenides (TMDs), carbon nanotubes (CNTs) and graphene. Graphene is a zero bandgap, 2D semiconductor material (consisting of a single layer of carbon atoms arranged in a honeycomb planar nanostructure) having high electron mobility. Compared to traditional field-effect transistors, graphene FETs (GFETs) insert a thin graphene channel between the source and drain region to improve conductivity within the channel. Carbon nanotube FETs (CNTFETs) utilize a single carbon nanotube (a 1D material consisting essentially of a rolled up sheet of graphene) or an array of carbon nanotubes as the channel material in a traditional FET structure. TMDs are another class of 2D materials that are made up of a transition metal (such as, e.g., molybdenum (Mo), tungsten (W), vanadium (V), etc.) and a chalcogen (e.g., sulfur(S), selenium (Se), tellurium (Te), etc.). Examples TMDs include, but are not limited to, molybdenum disulfide (MoS₂), tungsten disulfide (WS₂), molybdenum diselenide (MoSe₂), tungsten diselenide (WSe₂) and molybdenum telluride (MoTe₂). While graphene boasts high electron mobility, making it attractive for high-speed devices, TMDs possess a bandgap, allowing for better control over the on/off state in TMD FETs, making them ideal for logic applications.

The techniques disclosed herein can be used to form a metal-semiconductor contact on a surface of a semiconductor substrate. In some embodiments, additional steps may be performed to reduce a resistivity of the metal-semiconductor contact formed on the substrate surface. In one example embodiment, the semiconductor substrate 210 may be exposed to borane, diborane or phosphine gas before the surface of the semiconductor substrate 210 is exposed to the dry vapor 215 (in step 110 or step 320). This reduces resistivity of the subsequently formed metal-semiconductor contact by doping the semiconductor substrate 210 with boron, phosphorus, etc. In another example embodiment, the resistivity of the metal-semiconductor contact may be reduced by annealing the semiconductor substrate 210 after the elemental Sb film 230 is formed on the substrate surface. During the anneal step, the substrate temperature may be elevated to a high temperature between 400° C. and 550° C. for several milliseconds up to about 1 minute.

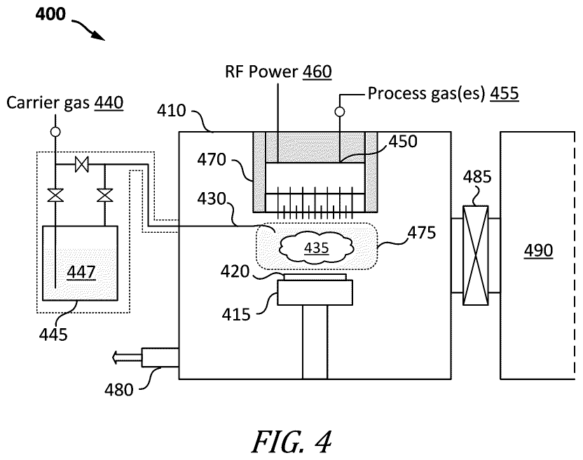

FIG. 4 illustrates one embodiment of a processing system 400 that utilizes the techniques disclosed herein to deposit an elemental Sb film on a semiconductor substrate. As shown in FIG. 4, the processing system 400 includes a reaction chamber 410, which in some embodiments, may be a pressure controlled chamber. A substrate holder 415 is provided within the reaction chamber 410 for holding a semiconductor substrate 420. The substrate holder 415 may generally include a heater (not shown) for heating the semiconductor substrate 420 to a desired temperature. In some cases, the substrate holder 415 may comprise a lower electrode, which is grounded or coupled to an impedance matching network and radio frequency (RF) bias power supply for receiving an RF bias voltage.

A first gas injection nozzle 430 is provided within the reaction chamber 410 for supplying a dry vapor 435 containing at least one vaporized antimony halide precursor to the processing space within the reaction chamber 410. In some embodiments, the dry vapor 435 may be created by bubbling a carrier gas 440 (e.g., Ar) into a container 445 comprising at least one liquid antimony halide precursor 447 (such as, e.g., SbCl₃ or SbCl₅). The dry vapor 435 containing the vaporized antimony halide precursor is supplied through various gas lines and valves to the first gas injection nozzle 430, where it is dispensed into the reaction chamber 410 to deposit an antimony-containing film or an elemental antimony film on the substrate surface. In some cases, the container 445 and gas lines of the bubbler system may be heated to generate and/or maintain the vaporized antimony halide precursor.

A second gas injection nozzle 450 is provided within the reaction chamber 410 for supplying additional process gas(es) 455, such as hydrogen (H₂) gas and optionally one or more inert gases (e.g., noble gases, such as argon (Ar), nitrogen (N₂), helium (He), etc.) to the processing space within the reaction chamber 410. An RF power supply 460 is coupled for supplying an RF source voltage to an upper electrode 470 provided within the reaction chamber 410. The RF source voltage supplied to the upper electrode 470 creates an electric field, which ionizes the H₂ gas and generates reactive species (such as ions, radicals, and energy-rich molecules) to form an H₂ plasma 475. The reactive species within the H₂ plasma 475 may react with the antimony halide precursor(s) within the dry vapor 435 and/or the antimony-containing film growing on the substrate surface, depending on the deposition process performed within the reaction chamber 410.

A variety of deposition processes may be performed within the reaction chamber 410. For example, a plasma enhanced chemical vapor deposition (PECVD) process or a plasma enhanced atomic layer deposition (PEALD) process may be performed within the reaction chamber 410, as described above. During the deposition processes described herein, the dry vapor 435 containing the vaporized antimony halide precursor(s) and the H₂ plasma 475 are supplied to the processing space within the reaction chamber 410 simultaneously or with at least partial temporal overlap (in the case of PECVD), or sequentially with no temporal overlap (in the case of PEALD), to form an elemental antimony (Sb) film on the surface of the semiconductor substrate 420. An exhaust port 480 is provided within the reaction chamber 410 for evacuating the reaction chamber 410 to a relatively low vacuum pressure (e.g., 20 Torr or less), while the antimony deposition process is carried out and for removing excess reactants and reaction by-products from the processing space.

In some embodiments, one or more additional processes may be performed within the reaction chamber 410 before or after the antimony deposition process is performed. For example, a cleaning process may be performed within the reaction chamber 410 before the antimony deposition process is performed to remove contaminants from the substrate surface before depositing the elemental Sb film on the surface of the semiconductor substrate 420. In another example, a substrate doping process may be performed within the reaction chamber 410 before the antimony deposition process is performed to inject dopants within the semiconductor substrate 420. In yet another example, a nitridation process may be performed within the reaction chamber 410 after the antimony deposition process is performed to form a thin nitride layer on the elemental Sb film. Examples of such processes are provided above.

As noted above, the optional cleaning process, the optional substrate doping process, the antimony deposition process and the optional nitridation process are preferably performed under vacuum and anhydrous conditions to prevent contamination and reoxidation of the elemental Sb film. In some cases, one or more of these optional processes may be performed outside of the reaction chamber 410 within another process chamber 490. In such embodiments, the reaction chamber 410 may be coupled to the process chamber 490 through a gate valve 485, as shown in FIG. 4. This enables the semiconductor substrate 420 to be transferred from the reaction chamber 410 to the process chamber 490 under vacuum.

Systems, process flows and methods to form an elemental antimony (Sb) film on a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for depositing an antimony film on a semiconductor substrate, the method comprising:
exposing a surface of the semiconductor substrate to a dry vapor containing at least one antimony halide precursor, wherein the dry vapor does not contain an organic antimony precursor or any other precursor containing carbon (C), silicon (Si), nitrogen (N) or oxygen (O); and
exposing the surface of the semiconductor substrate to a hydrogen (H₂) plasma before, during or after said exposing the surface of the semiconductor substrate to the dry vapor to deposit an elemental antimony (Sb) film on the surface of the semiconductor substrate.

2. The method of claim 1, wherein said exposing the surface of the semiconductor substrate to the dry vapor and said exposing the surface of the semiconductor substrate to the H₂ plasma are performed under vacuum and anhydrous conditions.

3. The method of claim 1, wherein the at least one antimony halide precursor is antimony trichloride (SbCl₃), antimony pentachloride (SbCl₅), antimony triiodide (SbI₃), antimony tribromide (SbBr₃), antimony trifluoride (SbF₃), or antimony pentafluoride (SbF₅).

4. The method of claim 1, wherein the at least one antimony halide precursor is antimony trichloride (SbCl₃), antimony pentachloride (SbCl₅) or a mixture thereof.

5. The method of claim 1, wherein said exposing the surface of the semiconductor substrate to the dry vapor and said exposing the surface of the semiconductor substrate to the H₂ plasma are performed with at least partial temporal overlap in a plasma enhanced chemical vapor deposition (PECVD) process.

6. The method of claim 1, wherein said exposing the surface of the semiconductor substrate to the dry vapor and said exposing the surface of the semiconductor substrate to the H₂ plasma are performed sequentially with no temporal overlap in a plasma enhanced atomic layer deposition (PEALD) process.

7. The method of claim 6, wherein said exposing the surface of the semiconductor substrate to the dry vapor and said exposing the surface of the semiconductor substrate to the H₂ plasma are repeated multiple times until a desired thickness of the elemental Sb film is deposited on the surface of the semiconductor substrate.

8. The method of claim 6, further comprising exposing the surface of the semiconductor substrate to an inert gas plasma during said exposing the surface of the semiconductor substrate to the dry vapor.

9. The method of claim 1, wherein prior to said exposing the surface of the semiconductor substrate to the dry vapor, the method further comprises:
cleaning the surface of the semiconductor substrate, wherein said cleaning removes contaminants from the surface of the semiconductor substrate; and
maintaining the semiconductor substrate under vacuum during said cleaning, and between said cleaning and said exposing the surface of the semiconductor substrate to the dry vapor, to prevent reoxidation of the surface of the semiconductor substrate.

10. The method of claim 9, where said cleaning comprises:
exposing the semiconductor substrate to a hydrogen-containing vapor, wherein the hydrogen-containing vapor comprises at least one of hydrogen (H₂), hydrogen fluoride (HF) and ammonia (NH₃); and
maintaining or heating the semiconductor substrate to a temperature between 20° C. and 500° C. during said exposing the semiconductor substrate to the hydrogen-containing vapor.

11. The method of claim 10, where said heating the semiconductor substrate comprises exposing the semiconductor substrate to a noble gas plasma.

12. The method of claim 9, where said cleaning comprises performing an atomic layer etching (ALE) process to remove the contaminants from the surface of the semiconductor substrate.

13. The method of claim 1, wherein after the elemental Sb film is deposited on the surface of the semiconductor substrate, the method further comprises:
exposing the semiconductor substrate to a nitrogen-containing vapor and/or a nitrogen-containing plasma to form an antimony nitride layer on an exposed surface of the elemental Sb film; and
maintaining the semiconductor substrate under vacuum during said exposing the semiconductor substrate to the nitrogen-containing vapor and/or the nitrogen-containing plasma.

14. The method of claim 13, wherein said exposing the semiconductor substrate to the nitrogen-containing vapor and/or the nitrogen-containing plasma comprises:
exposing the semiconductor substrate to one or more of: an ammonia (NH₃) vapor, a hydrazine (N₂H₄) vapor, a nitrogen (N₂) vapor and a nitrogen (N₂) plasma.

15. The method of claim 1, further comprising continuing said exposing the surface of the semiconductor substrate to the dry vapor and said exposing the surface of the semiconductor substrate to the H₂ plasma until the elemental Sb film is deposited to a desired thickness to form a metal-semiconductor contact on the surface of the semiconductor substrate.

16. A method for forming a metal-semiconductor contact on a semiconductor substrate, the method comprising:
cleaning a surface of the semiconductor substrate to remove surface contaminants from the surface of the semiconductor substrate;
exposing the surface of the semiconductor substrate to a dry vapor containing at least one antimony chloride precursor, wherein the dry vapor does not contain an organic antimony precursor or any other precursor containing carbon (C), silicon (Si), nitrogen (N) or oxygen (O);
exposing the surface of the semiconductor substrate to a hydrogen (H₂) plasma before, during or after said exposing the surface of the semiconductor substrate to the dry vapor to deposit an elemental antimony (Sb) film on the surface of the semiconductor substrate; and
continuing said exposing the surface of the semiconductor substrate to the dry vapor and said exposing the surface of the semiconductor substrate to the H₂ plasma until the elemental Sb film is deposited to a desired thickness to form the metal-semiconductor contact on the surface of the semiconductor substrate.

17. The method of claim 16, wherein the at least one antimony chloride precursor is antimony trichloride (SbCl₃), antimony pentachloride (SbCl₅) or a mixture thereof.

18. The method of claim 16, wherein said exposing the surface of the semiconductor substrate to the dry vapor and said exposing the surface of the semiconductor substrate to the H₂ plasma are performed with at least partial temporal overlap in a plasma enhanced chemical vapor deposition (PECVD) process.

19. The method of claim 16, wherein said exposing the surface of the semiconductor substrate to the dry vapor and said exposing the surface of the semiconductor substrate to the H₂ plasma are performed sequentially with no temporal overlap in a plasma enhanced atomic layer deposition (PEALD) process.

20. The method of claim 16, wherein said cleaning, said exposing the surface of the semiconductor substrate to the dry vapor, and said exposing the surface of the semiconductor substrate to the H₂ plasma are performed under vacuum and anhydrous conditions.

21. The method of claim 16, wherein after the elemental Sb film is deposited on the surface of the semiconductor substrate, the method further comprises:
exposing the semiconductor substrate to a nitrogen-containing vapor and/or a nitrogen-containing plasma to form an antimony nitride layer on an exposed surface of the elemental Sb film; and
wherein said exposing the semiconductor substrate to the nitrogen-containing vapor and/or the nitrogen-containing plasma is performed under vacuum and anhydrous conditions.

22. The method of claim 16, wherein the semiconductor substrate comprises transition metal dichalcogenides, carbon nanotubes or graphene.

23. The method of claim 16, wherein the semiconductor substrate comprises a III-V semiconductor material or a II-VI semiconductor material.

24. The method of claim 16, wherein the semiconductor substrate comprises silicon (Si), germanium (Ge) or a mixture thereof.

25. The method of claim 16, further comprising reducing a resistivity of the metal-semiconductor contact by performing one or more of the following:
exposing the semiconductor substrate to borane, diborane or phosphine gas prior to said exposing the surface of the semiconductor substrate to the dry vapor; and
annealing the semiconductor substrate to a temperature between 400° C. and 550° C. after the elemental Sb film is formed on the surface of the semiconductor substrate.
